(19) United States
(12) Patent Application Publication
(10) Pub. No.: US 2011/0084292 A1
(43) Pub. Date: Apr. 14, 2011

(54) ARRAYS OF LIGHT EMITTING DEVICES

(75) Inventor: Donald L. McDaniel, JR., North Andover, MA (US)

(73) Assignee: Luminus Devices, Inc., Billerica, MA (US)

(21) Appl. No.: 12/896,113

(22) Filed: Oct. 1, 2010

Related U.S. Application Data
(60) Provisional application No. 61/247,862, filed on Oct. 1, 2009.

(51) Int. Cl. H01L 33/50; H01L 33/08; G06F 17/50

(52) U.S. Cl. 257/89; 257/93; 716/132; 257/E33.005; 257/E33.067

(57) ABSTRACT

Arrays of light-emitting devices, and related components, processes, systems and methods are disclosed.

### RELATED APPLICATIONS

This application claims priority to U.S. Provisional Application No. 61/247,862, filed Oct. 1, 2009, which is incorporated herein by reference in its entirety.

### TECHNICAL FIELD

The invention relates to light-emitting devices, and related components, processes, systems and methods.

### BACKGROUND

A light emitting diode (LED) often can provide light in a more efficient manner than an incandescent light source and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays.

Typically, an LED is formed of multiple layers, with at least some of the layers being formed of different materials. In general, the materials and thicknesses selected for the layers determine the wavelength(s) of light emitted by the LED. In addition, the chemical composition of the layers can be selected to try to isolate injected electrical charge carriers into regions (commonly referred to as quantum wells) for relatively efficient conversion to optical power. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

A common approach to preparing an LED is as follows. The layers of material are prepared in the form of a wafer. Typically, the layers are formed using an epitaxial deposition technique, such as metal-organic chemical vapor deposition (MOCVD), with the initially deposited layer being formed on a growth substrate. The layers are then exposed to various etching and metallization techniques to form contacts for electrical current injection, and the wafer is subsequently sectioned into individual LED chips. Usually, the LED chips are packaged.

During use, electrical energy is usually injected into an LED and then converted into electromagnetic radiation (light), some of which is extracted from the LED.

Conventional systems can be configured such that the array of light emitting devices comprises light emitting devices having equal emitting areas and often the same aspect ratio of the surface of the light emitting devices. For example, an array of four light emitting devices wherein each light emitting device has a 12 mm² emitting area and a 3×4 aspect ratio of the surface of the light emitting device. Such systems may have non-optimum emission efficiency, especially when light emission having a particular color is produced by selecting each light emitting device with a particular color point, or chromaticity, and maximizing light output in the same time.

FIGS. 3, 3A, and 3B show exemplary light emitting device (LED) die orientations for multi-chip arrays employed in the prior art. FIG. 3 shows an array 100 of light emitting devices that includes two LEDs 102 and 104 arranged in a single row. The emitting area of LED 102 is equal to emitting area of LED 104. FIG. 3A shows an array 110 of light emitting devices that includes four LEDs 112, 114, 116, and 118 arranged in a 2×2 matrix (i.e., arranged in two rows and two columns). The array is configured such that each LED in the array has an equal to each other emitting areas (the emitting area of LED 112 is equal to emitting area of LED 114, LED 116, and LED 118). FIG. 3B shows an array 120 of light emitting devices that includes twelve LEDs 122, 123, 124, 125, 126, 127, 128, 129, 130, 131, 132, 133 arranged in a 3×4 matrix (i.e., arranged in three rows and four columns). The array is configured such that each LED in the array has an equal to each other emitting areas (the emitting area of LED 122 is equal to emitting area of LED 123, 124, 125, 126, 127, 128, 129, 130, 131, 132, and 133).

### SUMMARY

The invention relates to arrays of light-emitting devices, and related components, systems and methods.

In one embodiment, a system includes a substrate and an array of light emitting devices supported by the substrate. The array of light emitting devices being configured such that at least one of the light emitting devices in the array has an emitting area different than an emitting area of the other light emitting devices in the array.

In another embodiment of the present invention, a system includes a substrate and an array of light emitting devices supported by the substrate. The array of light emitting devices has all the light emitting devices with different than each other emitting areas.

In another embodiment of the present invention, a system includes a substrate and an array of light emitting devices supported by the substrate. The array of light emitting devices comprises two light emitting devices with unequal emitting areas. The array could be formed of Red, Green, Blue, White, UV light emitting device, or combinations thereof.

In another embodiment of the present invention, a system includes a substrate and an array of light emitting devices supported by the substrate. The array of light emitting devices comprises three light emitting devices. The array could be formed of Red, Green, Blue, White, UV LED or combinations thereof. The array of light emitting devices is configured such that two light emitting devices have equal emitting areas and the other light emitting device has an emitting area different than that of said two light emitting devices. The three light emitting devices could be disposed randomly, or in a matrix having two rows and two columns, or in a rectangular matrix having one row and three columns.

In another embodiment of the present invention, a system includes a substrate and an array of light emitting devices supported by the substrate. The array of light emitting devices comprises three light emitting devices. The array of light emitting devices is configured such that the three light emitting devices of said array have emitting areas different from each other. The array could be formed of Red, Green, Blue, White, UV light emitting device, or combinations thereof. The three light emitting devices could be disposed randomly, or in a matrix having two rows and two columns, or in a rectangular matrix having one row and three columns.

In another embodiment of the present invention, a system includes a substrate and an array of light emitting devices supported by the substrate. The array of light emitting devices comprises four light emitting devices. The array of light emitting devices is configured such that three light emitting devices have equal emitting areas, and the other light emitting device has emitting area different from those of said three light emitting devices. The array could be formed of Red, Green, Blue, White, UV light emitting device, or combinations thereof. The four light emitting devices could be disposed randomly, or in a matrix having two rows and two columns, or in a rectangular matrix having one row and four columns.

In another embodiment of the present invention, a system includes a substrate and an array of light emitting devices supported by the substrate. The array of light emitting devices comprises four light emitting devices. The array of light emitting devices is configured such that the two light emitting devices in the array have equal emitting areas and the other two light emitting devices have equal emitting areas; the emitting area of the two devices is being different than the emitting area of the other two devices. The array could be formed of Red, Green, Blue, White, UV light emitting device, or combinations thereof. The four light emitting devices could be disposed randomly, or in a matrix having two rows and two columns, or in a rectangular matrix having one row and four columns.

In another embodiment of the present invention, a system includes a substrate and an array of light emitting devices supported by the substrate. The array of light emitting devices comprises four light emitting devices. The array of light emitting devices is configured such that two light emitting devices have equal emitting areas and the other two light emitting devices have different than each other and different than emitting areas of the other two light emitting devices. The array could be formed of Red, Green, Blue, White, UV light emitting device, or combinations thereof. The four light emitting devices could be disposed randomly, or in a matrix having two rows and two columns, or in a rectangular matrix having one row and four columns.

In another embodiment of the present invention, a system includes a substrate and an array of light emitting devices supported by the substrate. The array of light emitting devices comprises four light emitting devices. The array of light emitting devices is configured such that the four light emitting devices of said array have emitting areas different from each other. The array could be formed of Red, Green, Blue, White, UV light emitting device, or combinations thereof. The four light emitting devices could be disposed randomly, or in a matrix having two rows and two columns, or in a rectangular matrix having one row and four columns.

In another embodiment of the present invention, a system includes a substrate and an array of light emitting devices supported by the substrate. The array of light emitting devices comprises five light emitting devices. The array of light emitting devices is configured such that the four light emitting devices in the array have equal emitting areas and the other light emitting device has an emitting area different than that of said four light emitting devices. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises five light emitting devices. The array of light emitting devices is configured such that three light emitting devices have equal emitting areas and the other two light emitting devices have equal emitting areas; the emitting area of said three devices is being different than the emitting area of the other two devices. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises five light emitting devices. The array of light emitting devices is configured such that three light emitting devices have equal emitting areas and the other two light emitting devices have different than each other and different than emitting areas of the other three light emitting devices. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises five light emitting devices. The array of light emitting devices is configured such that two light emitting devices have equal emitting areas and the other three light emitting devices have different than each other and different than emitting areas of the other two light emitting devices. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises five light emitting devices. The array of light emitting devices is configured such that two light emitting devices have equal emitting areas and other two light emitting devices have equal emitting areas; the emitting area of the first two devices is being different than the emitting area of the other said two devices. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises five light emitting devices. The array of light emitting devices is configured such that the five light emitting devices of said array have emitting areas different from each other. The array could be formed of Red, Green, Blue, White, UV light emitting device, or combinations thereof. The five light emitting devices could be disposed randomly, or in a matrix having two rows and three columns, or in a rectangular matrix having one row and five columns.

In another embodiment of the present invention, a system includes a substrate and an array of light emitting devices supported by the substrate. The array of light emitting devices comprises six light emitting devices. The array of light emitting devices is configured such that the five light emitting devices in said array have equal emitting areas and the other light emitting device has an emitting area different than that of said five light emitting devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that four light emitting devices have equal emitting areas and the other two light emitting devices have equal emitting areas; the emitting area of the said four devices is being different than the emitting area of the other two devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that four light emitting devices have equal emitting areas and the other two light emitting devices have different than each other and different than emitting areas of the other four light emitting devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that two light emitting devices have equal emitting areas and the other four light emitting devices have different than each other and different than emitting areas of the other two light emitting devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that three light emitting devices have equal emitting areas and the other three light emitting devices have equal emitting areas; the emitting area of the said three devices is being different than the emitting area of the other three devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that three light emitting devices have equal emitting areas and the other three light emitting devices have different than each other and different than emitting areas of the other three light emitting devices. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that two light emitting devices have equal emitting areas and other two light emitting devices have equal emitting areas and the other two light emitting devices have equal emitting areas; the emitting area of each pair of light emitting devices is being different than each other. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that two light emitting devices have equal emitting areas (area 1), and another two light emitting devices have equal emitting areas (area 2), but the other two light emitting devices have unequal emitting areas (area 3 and area 4); emitting area 1, 2, 3, and 4 are being unequal to each other. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that three light emitting devices have equal emitting areas (area 1), another two light emitting devices have equal emitting areas (area 2), and the other light emitting device have emitting area (area 3) different than that of each pair; emitting area 1, 2, and 3 are being unequal to each other. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices comprises six light emitting devices. The array of light emitting devices is configured such that the six light emitting devices of said array have emitting areas different from each other. The array could be formed of Red, Green, Blue, White, UV light emitting device, or combinations thereof. The six light emitting devices could be disposed randomly, or in a rectangular matrix having two rows and three columns, or in a rectangular matrix having one row and six columns.

In another embodiment of the present invention, a system includes a substrate and an array of light emitting devices supported by the substrate. The array of light emitting devices can comprise one or more of the following: a Red LED, Green LED, Blue LED, and White LED. In some cases, the array is configured such that the ratio of the emitting area of the Red LED to the emitting area of the Green LED is in the range from 0.7 to 1.3. In some cases, the array is configured such that the ratio of the emitting area of the Blue LED to the emitting area of the Red LED is in the range from 0.15 to 0.75. In some cases, the array is configured such that the ratio of the emitting area of the Blue LED to the emitting area of the Green LED is in the range from 0.15 to 0.75. In some cases, the array is configured such that the ratio of the emitting area of the Blue LED to the emitting area of the White LED is in the range from 0.3 to 0.9. In some cases, the array is configured such that the ratio of the emitting area of the White LED to the emitting area of the Red LED is in the range from 0.45 to 1.05. In some cases, the array is configured such that the ratio of the emitting area of the White LED to the emitting area of the Green LED is in the range from 0.45 to 1.05. It should be understood that an array may include one or any combination of the above-noted ratios of emitting areas including all of the above-noted ratios.

In another embodiment of the present invention, a system includes a substrate and an array of light emitting devices supported by the substrate. The array of light emitting devices consists of a Red LED having an emitting area equal to about 12 mm², a Green LED having an emitting area equal to about 12 mm², a Blue LED having an emitting area equal to about 5.4 mm², and a White LED having an emitting area equal to about 9 mm².

Some embodiments could further comprise a package containing the substrate and the array of light emitting devices. The package could have a layer configured so that at least about 75% of the light that emerges from the light emitting devices and impinges on the layer passes through the layer, wherein the layer is disposed such that a distance between a surface of the array of light emitting devices and a surface of the layer nearest to the surface of the array of light emitting devices is from about five microns to about 400 microns.

In some embodiments, the array of light emitting devices is configured such that for any given pair of LEDs having unequal emitting areas, the ratio of emitting area of a smaller LED to the emitting area of a larger LED is in the range from 0.07 to 0.96.

In some embodiments, the array of light emitting devices can consist of 2*N light emitting devices where N is a positive integer and the 2*N light emitting devices disposed in a rectangular matrix having N rows and two columns.

In some embodiments, the array of light emitting devices being positioned such that a ratio of a sum of a total area of all of the light emitting devices in the array of light emitting devices to the area defined by the outer perimeter is at least about 0.75.

In some embodiments, the array of light emitting devices being positioned such that the spacing between the nearest edges of neighboring light emitting devices in the array is no more than 200 microns.

In some embodiments, the light emitting devices that have equal emitting areas can also have different aspect ratio of the surface of light emitting devices.

In some embodiments, at least one of the light emitting devices in the array of light emitting devices can include a multi-layer stack of materials that includes a first layer supported by the light generating region. A surface of the first layer can be configured so that light generated by the light generating region can emerge from the light emitting device via a surface of the first layer. The surface of the first layer can have a dielectric function that varies spatially according to a pattern. The pattern can have an ideal lattice constant and a detuning parameter with a value greater than zero. The surface of the first layer can have a dielectric function that varies spatially according to a non-periodic pattern. The surface of the first layer can have a dielectric function that varies spatially according to a quasicrystalline pattern. The surface of the first layer can have a dielectric function that varies spatially according to a complex periodic pattern. The surface of the first layer can have a dielectric function that varies spatially according to a periodic pattern.

The light emitting device can have an edge that is at least about one millimeter long. The light emitting device can have an edge that is at least about 1.5 millimeters.

The layer can include at least one optical component. The optical component can include a photonic lattice, a color filter, a polarization selective layer, a wavelength conversion layer, and/or an anti-reflective coating.

The package can also include a heat sink layer. The package can be mounted on a heat sink device. The package can be mounted on a heat sink device. The package can include a package substrate. The package substrate can be formed of Al, N, Cu, C, Au or combinations thereof. The package can be mounted on a thermoelectric cooler. The light emitting device can be a light emitting diode. The light emitting diode can be a photonic lattice light emitting diode. The light emitting device can be a surface emitting laser. The light emitting device can be a light emitting diode, a laser, an optical amplifier, and/or combinations thereof. The light emitting device can be an OLED, a flat surface-emitting LED, a HBLED, and/or combinations thereof. The system can also include a cooling system configured so that, during use, the cooling system regulates a temperature of the light emitting diode.

The array of light emitting devices can include a plurality of light emitting devices connected electrically in series. The array of light emitting devices can include a plurality of light emitting devices connected electrically in parallel.

Features and advantages of the invention are in the description, drawings and claims.

In some embodiments, a method of optimizing an LED system for minimum total die area and device junction temperature while maximizing luminous flux is disclosed. The method comprises the following steps: selecting the white point for which the system is to be optimized, selecting a color bin for the White LED, computing what Red, Green, Blue and White lumens are required to achieve the target optimized white point, establishing minimum flux thresholds for each of the primaries to further constrain the solution space, determining dependence of luminous flux on current density for each LED, determining dependence of die temperature on electrical power for each LED, and performing the optimization for chromaticity by optimizing die area and die junction temperature for each LED while maximizing luminous flux and minimizing the total die area of the system.

The preceding summary, as well as the following detailed description of the invention, will be better understood when read in conjunction with the attached drawings. For the purpose of illustration the invention, presently preferred embodiments are shown in the drawings. It should be understood, however, that the invention is not limited to the precise arrangements and instrumentalities shown.

### DESCRIPTION OF DRAWINGS

FIG. 1 is a schematic representation of a light-emitting system.

FIG. 2 is a cross-sectional view of a packaged light emitting device.

FIG. 3 is a top view of an array of light emitting devices.

FIG. 3A is a top view of an array of light emitting devices.

FIG. 3B is a top view of an array of light emitting devices.

FIG. 4 is a top view of an array of light emitting devices.

FIG. 5 is a top view of an array of light emitting devices.

FIG. 5A is a top view of an array of light emitting devices.

FIG. 6 is a top view of an array of light emitting devices.

FIG. 6A is a top view of an array of light emitting devices.

FIG. 7 is a top view of an array of light emitting devices.

FIG. 7A is a top view of an array of light emitting devices.

FIG. 8 is a top view of an array of light emitting devices.

FIG. 8A is a top view of an array of light emitting devices.

FIG. 9 is a top view of an array of light emitting devices.

FIG. 9A is a top view of an array of light emitting devices.

FIG. 10 is a top view of an array of light emitting devices.

FIG. 10A is a top view of an array of light emitting devices.

FIG. 10B is a top view of an array of light emitting devices.

FIG. 11 is a cross-sectional view of a packaged light emitting device.

FIG. 12 is a top view of an array of light emitting devices forming a closely packed configuration.

FIG. 13 is a block diagram corresponding to the method of system optimization.

### DETAILED DESCRIPTION

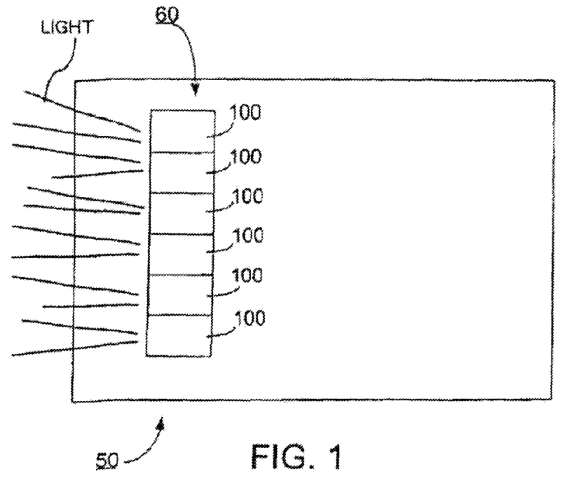

FIG. 1 is a schematic representation of a light-emitting system 50 that has an array 60 of LEDs 100 incorporated therein. Array 60 is configured so that, during use, light that emerges from LEDs 100 emerges from system 50.

Examples of light-emitting systems include projectors (e.g., rear projection projectors, front projection projectors), portable electronic devices (e.g., cell phones, personal digital assistants, laptop computers), computer monitors, large area signage (e.g., highway signage), vehicle interior lighting (e.g. dashboard lighting), vehicle exterior lighting (e.g., vehicle headlights, including color changeable headlights), general lighting (e.g., office overhead lighting), high brightness lighting (e.g., streetlights), camera flashes, medical devices (e.g., endoscopes), telecommunications (e.g., plastic fibers for short range data transfer), security sensing (e.g. biometrics), integrated optoelectronics (e.g., intrachip and interchip optical interconnects and optical clocking), military field communications (e.g., point to point communications), biosensing (e.g., photo-detection of organic or inorganic substances), photodynamic therapy (e.g., skin treatment), night vision goggles, solar powered transit lighting, emergency lighting, airport runway lighting, airline lighting, surgical goggles, wearable light sources (e.g., lifevests). An example of a rear projection projector is a rear projector television. An example of a front projection projector is a projector for displaying on a surface, such as a screen or a wall. In some embodiments, a laptop computer can include a front projection projector.

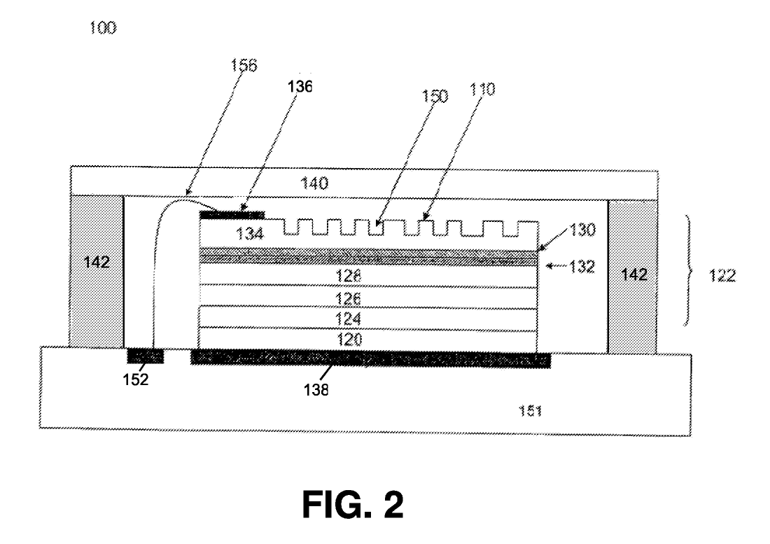

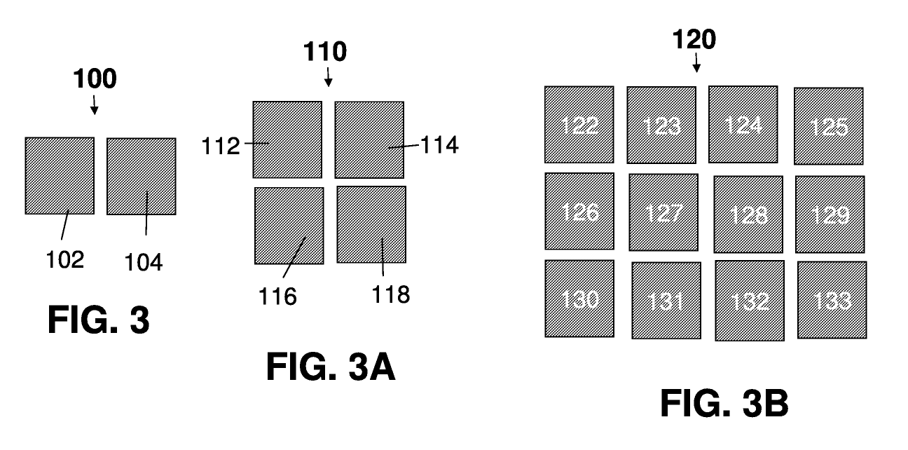

FIG. 2 shows a side view of an LED 100 in the form of a packaged die. LED 100 includes a multi-layer stack 122 disposed on a submount 120. Multi-layer stack 122 includes a 320 nm thick silicon doped (n-doped) GaN layer 134 having a pattern of openings 150 in its upper surface 110. Multi-layer stack 122 also includes a bonding layer 124, a 100 nm thick silver layer 126, a 40 nm thick magnesium doped (p-doped) GaN layer 128, a 120 nm thick light-generating region 130 formed of multiple InGaN/GaN quantum wells, and a AlGaN layer 132. An n-side contact pad 136 is disposed on layer 134. Packaged LED 100 also includes a package substrate 151 and metalized portions 152 and 138 supported by substrate 151. Metallized portion 152 is electrically connected to n-side contact 136 using a connector 156, for example, a wire bond. Metallized portion 138 is in electrical contact with conductive submount 120 and forms an electrical current path to p-doped layer 128. A frame 142 is supported by substrate 151. Frame 142 supports a transparent cover 140. Typically, transparent cover 140 is formed of a material that transmits at least about 60% (e.g., at least about 70%, at least about 80%, at least about 90%, at least about 95%) of the light that emerges form LED 100 and impinges on transparent cover 140.

Light is generated by LED 100 as follows. P-side contact 138 is held at a positive potential relative to n-side contact 136, which causes electrical current to be injected into LED 100. As the electrical current passes through light-generating region 130, electrons from n-doped layer 134 combine in region 130 with holes from p-doped layer 128, which causes region 130 to generate light. Light-generating region 130 contains a multitude of point dipole radiation sources that emit light (e.g., isotropically) within region 130 with a spectrum of wavelengths characteristic of the material form which light-generating region 130 is formed. For InGaN/GaN quantum wells, the spectrum of wavelengths of light generated by region 130 can have a peak wavelength of about 445 nanometers (nm) and a full width at half maximum (FWHM) of about 30 nm.

It is to be noted that the charge carriers in p-doped layer 126 have relatively low mobility compared to the charge carriers in the n-doped semiconductor layer 134. As a result, placing silver layer 126 (which is conductive) along the surface of p-doped layer 128 can enhance the uniformity of charge injection from contact 138 into p-doped layer 128 and light-generating region 130. This can also reduce the electrical resistance of device 100 and/or increase the injection efficiency of device 100. Because of the relatively high charge carrier mobility of the n-doped layer 134, electrons can spread relatively quickly from n-side contact pad 136 throughout layer 134, so that the current density within light-generating region 130 is substantially uniform across region 130. It is also to be noted that silver layer 126 has relatively high thermal conductivity, allowing layer 126 to act as a heat sink for LED 100 (to transfer heat vertically form multi-layer stack 122 to submount 120).

At least some of the light that is generated by region 130 is directed toward silver layer 126. This light can be reflected by layer 126 and emerge from LED 100 via surface 110, or can be reflected by layer 126 and then absorbed within the semiconductor material in LED 100 via surface 110, or can be reflected by layer 126 and then absorbed within the semiconductor material in LED 100 to produce an electron-hole pair that can combine in region 130, causing region 130 to generate light. Similarly, at least some of the light that is generated by region 130 is directed toward pad 136. The underside of pad 136 is formed of a material (e.g., a Ti/Al/Ni/Au alloy) that can reflect at least some of the light generated by light-generating region 130. Accordingly, the light that is directed to pad 136 can be reflected by pad 136 and subsequently emerge from LED 100 via surface 110 (e.g., by being reflected from silver layer 126), or the light that is directed to pad 136 can be reflected by pad 136 and then absorbed within the semiconductor material in LED 100 to produce an electron-hole pair that can combine in region 130, causing region 130 to generate light (e.g., with or without being reflected by silver layer 126).

As shown in FIG. 2, surface 110 of LED 100 is not flat but consists of a pattern of openings 150. In general, various values can be selected for the depth of openings 150, the diameter of openings 150 and the spacing between nearest neighbors in openings 150 can vary. Examples of patterns transferred into the surface include a variety of patterns that can increase extraction efficiency from the light emitting device. For example, patterns having a detuned quasicrystalline or complex periodic structures, periodic patterns, and non-periodic patterns. A complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimedean patterns. Complex periodic pattern can have certain openings with one diameter and other openings with a smaller diameter. As referred to herein, a nonperiodic pattern is a pattern that has no translational symmetry over a unit cell that has a length that is at least 50 times the peak wavelength of light generated by region 130. Examples of nonperiodic patterns include aperiodic patterns, quasicrystalline patterns, Robinson patterns, and Amman patterns. As referred to herein, a detuned pattern is a pattern with nearest neighbors in the pattern having a center-to-center distance with a valued between (a−Δa) and (a+Δa), where “a” is the lattice constant for the pattern and “Δa” is a detuning parameter with dimensions of length and where the detuning can occur in random directions. To enhance light extraction from LED 100, detuning parameter, Δa, is generally at least about one percent (e.g., at least about two percent, at least about three percent, at least about four percent, at least about three percent, at least about five percent) of ideal lattice constant, a. In some embodiments, the nearest neighbor spacings vary substantially randomly between (a−Δa) and (a+Δa), such that the pattern is substantially randomly detuned.

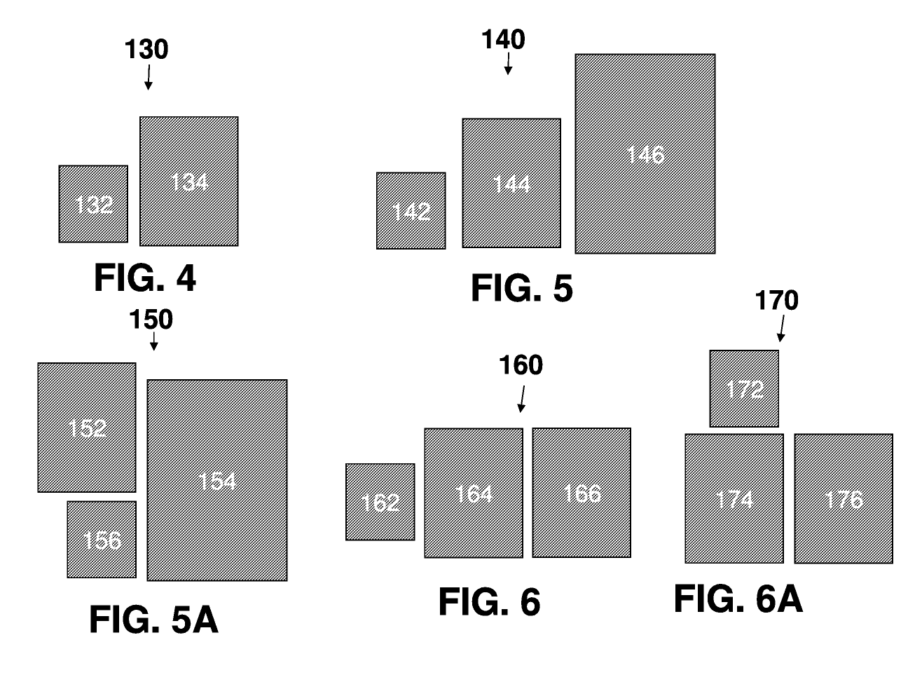

FIGS. 4, 5, 5A, 6, 6A, 7, 7A, 8, 8A, 9, 9A, 10, 10A, and 10B, 11, and 12 show some exemplary embodiments of the present invention illustrating die orientations for multi-chip arrays. Such embodiments include with an array of light emitting devices in which one or more of the devices have unequal emitting areas. As shown, the emitting areas may be the areas of the surface (e.g., top surface of the device) through which light is emitted. This may improve efficiency from the array while achieving a required by design light intensity (Lumens) and color point or chromaticity, resulting in more efficient and reliable systems than those utilized by the prior art inventions.

It should be understood that other array arrangements according to the invention are possible.

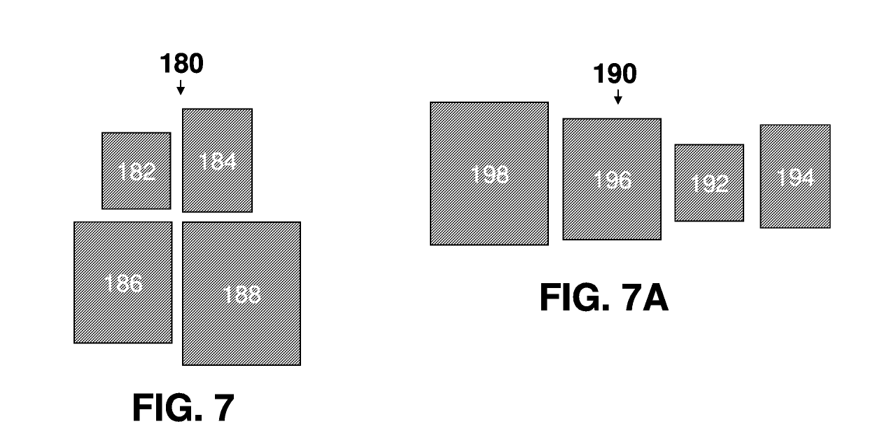

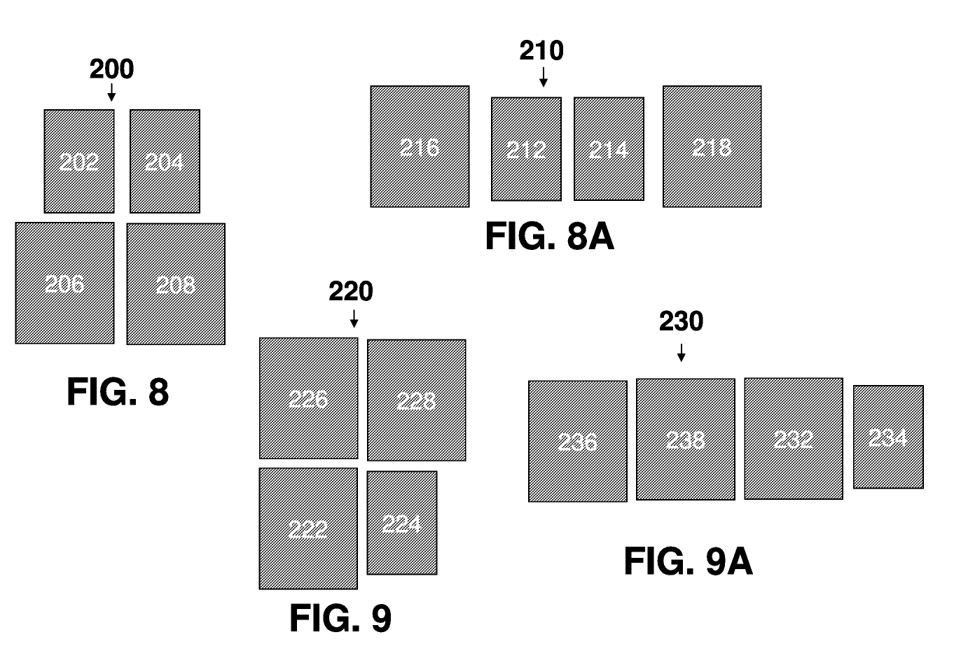

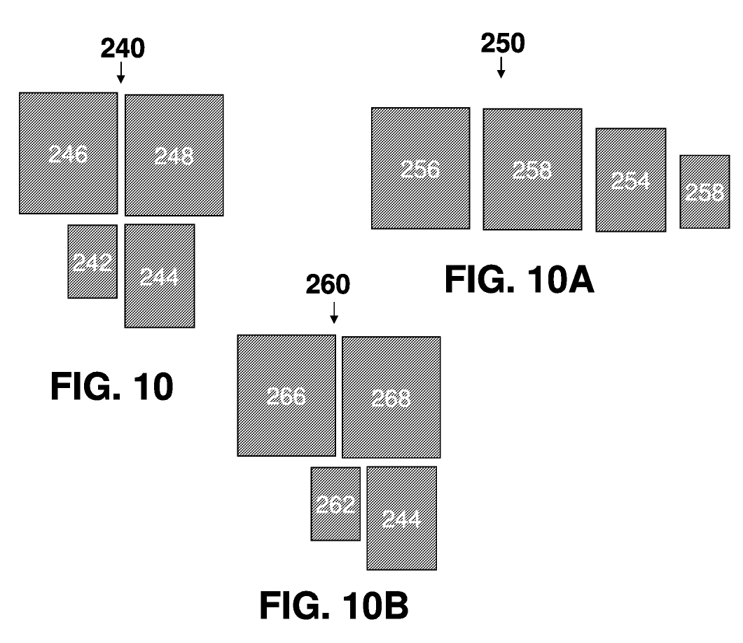

Note that in all of these embodiments the array could include any one or more of the following light emitting devices: Red, Green, Blue, White, UV light emitting device, and combinations thereof. FIG. 4 shows an array 130 of light emitting devices that includes two LEDs 132 and 134 arranged in a single row. Note that the emitting area of LED 132 is not equal to the emitting area of LED 134. FIG. 5 shows an array 140 of light emitting devices that includes three LEDs 142, 144, and 146 arranged in a single row. All LEDs in the array have unequal to each other emitting areas. FIG. 5A shows an array 150 of light emitting devices that includes three LEDs 152, 154, and 156 arranged in a 2×2 matrix (i.e., arranged in two rows and two columns) with emitting areas of each LED being unequal to each other. FIG. 6 shows an array 160 of light emitting devices that includes three LEDs 162, 164, and 166 arranged in a single row (i.e. arranged in one row and three columns), where the emitting area of LED 164 is equal to emitting area of LED 166 and is not equal to the emitting area of LED 162. FIG. 6A shows an array 170 of light emitting devices that includes three LEDs 172, 174, and 176 arranged in a 2×2 matrix (i.e., arranged in two rows and two columns), where the emitting area of LED 174 is equal to the emitting area of LED 176 and not equal to the emitting area of LED 172. FIG. 7 shows an array 180 of light emitting devices that includes four LEDs 182, 184, 186, and 188 arranged in a 2×2 matrix (i.e., arranged in two rows and two columns), where the emitting area of each LED is different from each other. The array could be formed of Red, Green, Blue, White, UV light emitting device, or combinations thereof. For example, LED 182 could be a Red LED, LED 184 could be a Green LED, LED 186 could be a Blue LED, and LED 188 could be a White LED. The selection of color for each LED is not limited by respective position of LEDs in the array (i.e., Red LED, for example, could be LED 182, or 184, or 186, or 188). All four LEDs in the array could be of the same color (e.g., LED 182, 184, 186, and 188 are all Red LEDs). The light emitting devices in the array could be arranged in a single row, as illustrated by FIG. 7A. FIG. 8 shows an array 200 of light emitting devices that includes four LEDs 202, 204, 206, and 208 arranged in a 2×2 matrix (i.e., arranged in two rows and two columns). The emitting areas of LEDs 202 and 204 are equal to each other and the emitting areas of LED 206 and 208 are equal to each other, but different than the emitting area of LED 202 and 204. The light emitting devices in the array could be arranged in a single row, as illustrated by FIG. 8A. In another embodiment, illustrated in FIG. 9, an array 220 of light emitting devices includes four LEDs arranged in a 2×2 matrix, where the emitting areas of LED 226, 222, and 228 are equal to each other and different from the emitting area of LED 224. The light emitting devices in the array could be arranged in a single row, as illustrated by FIG. 9A. The light emitting devices in the array could be arranged in a matrix or in a single row, or, as illustrated in FIG. 10B, could be arranged randomly (i.e., shifted horizontally or vertically in relation to other LEDs), where LED 262 and 244, for example, are shifted laterally in relation to LED 266 and 268, thus being arranged in a non-matrix configuration). In general, the number or rows and columns in the matrix of LEDs can be selected as desired. For example, an array of five or six LEDs, or an array of N times M LEDs arranged in an N by M matrix having N rows (e.g., a first row, a second row, and an N^{th} row) and M columns (e.g., a first columns, a second columns, and an M^{th} columns) of LEDs (where N and M are both positive integers). In some embodiments, the number of LEDs and the placement of each LED in the multi-chip array can be selected to form a desired aspect ratio, as defined by the length of array to the width of array. A desired aspect ratio can be obtained by appropriately sizing and/or spacing LED die.

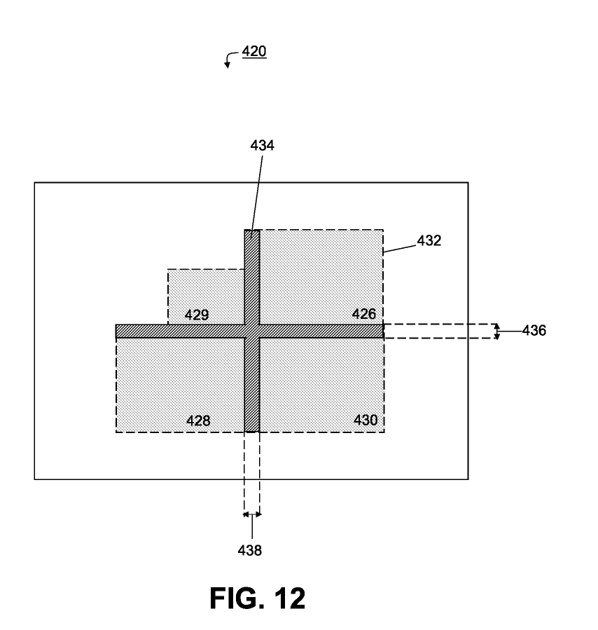

As mentioned above, multiple LEDs can be packed closely together in an array. As shown in FIG. 12, multiple LEDs 424, 426, 428, and 430 are supported by a substrate 422. The LEDs can be positioned on substrate 422 to reduce or minimize the spacing between adjacent LEDs. In some embodiments, LEDs 424, 426, 428, and 430 can be arranged such that a spacing between the nearest edges of neighboring die in the array of LEDs (e.g., spacing 436 and/or spacing 438) is relatively small. For example, spacing 436 or 438 can be at most about 250 microns (e.g., at most about 200 microns, at most about 150 microns, at most about 100 microns, at most about 75 microns, at most about 50 microns).

In some additional embodiments, LEDs 424, 426, 428, and 430, as shown in FIG. 12, can be arranged on substrate 422 to reduce or minimize the amount of surface area disposed between LEDs 424, 426, 428, and 430 (as indicated by area 434). In general, a total area of the LED array can be defined by eh area enclosed by an outer perimeter of the LEDs (e.g., as indicated by dashed line 432). A total surface area of the LEDs can be about equal to the sum of the area of each LED in the array of LEDs (e.g., a sum of the area of LEDs 424, 426, 428, and 430). In a close packed array of LEDs, the LEDs in the array of light emitting devices can be positioned such that a ratio of a sum of a total area of all of the light emitting devices (e.g., a sum of the areas LEDs 424, 426, 428, and 430) in the array to the total area 432 can be at least about 0.8 (e.g., at least about 0.85, at least about 0.9, at least about 0.95). In some embodiments, ratio of a sum of a total area of all of the light emitting devices in the array to the total area 432 can be at least about 0.5 (e.g., at least about 0.6, at least about 0.7).

In some embodiments, the array could be configured such that the ratio of the emitting area of the Red LED to the emitting area of the Green LED is in the range from 0.7 to 1.3; the ratio of the emitting area of the Blue LED to the emitting area of the Red LED is in the range from 0.15 to 0.75; the ratio of the emitting area of the Blue LED to the emitting area of the Green LED is in the range from 0.15 to 0.75; the ratio of the emitting area of the Blue LED to the emitting area of the White LED is in the range from 0.3 to 0.9; the ratio of the emitting area of the White LED to the emitting area of the Red LED is in the range from 0.45 to 1.05, and the ratio of the emitting area of the White LED to the emitting area of the Green LED is in the range from 0.45 to 1.05. For example, the array of light emitting devices could consist of a Red LED having an emitting area equal to about 12 mm², a Green LED having an emitting area equal to about 12 mm², a Blue LED having an emitting area equal to about 5.4 mm², and a White LED having an emitting area equal to about 9 mm².

In some embodiments, the array of light emitting devices could be configured such that for any given pair of LEDs having unequal emitting areas, the ratio of emitting area of a smaller LED to the emitting area of a larger LED is in the range from 0.07 to 0.96. For example, if LED 424 (FIG. 12) in the array has an emitting area equal to 1 mm² and another LED 430 in the array has an emitting area equal to 12 mm², then the ratio of the emitting area of the smaller LED to the emitting area of the larger LED would be 0.08.

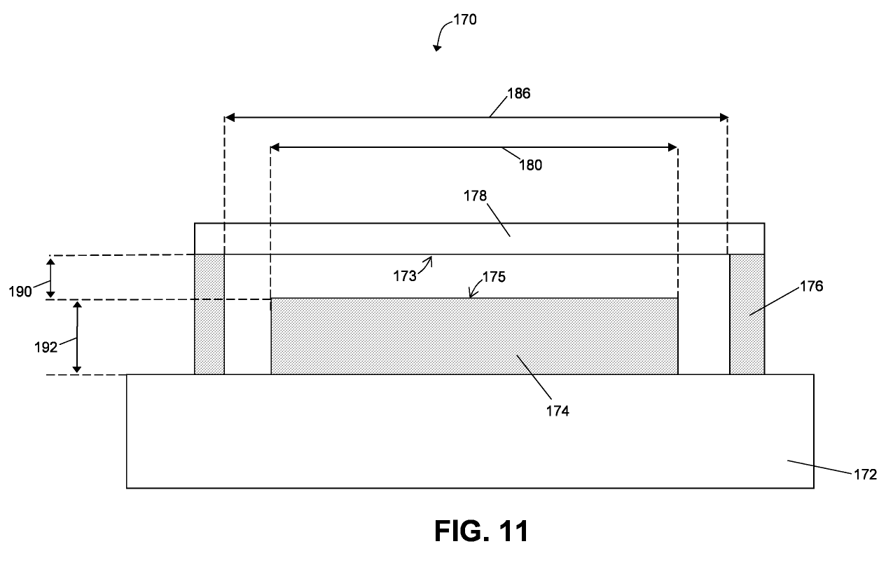

FIG. 11 shows a side view of an LED 174 in the form of a packaged die 170. The package includes a substrate 172 that supports LED 174. The package also includes a frame 176 and a transparent cover 178 supported by frame 176. Typically, transparent cover 178 is formed of a material that transmits at least about 60% (e.g., at least about 70%, at least about 80%, at least about 90%, at least about 95%) of the light that emerges from LED 174 and impinges on transparent cover 178. Examples of materials from which transparent cover 178 can be formed include glass, silica, quartz, plastic, and polymers. In general, the package should be capable of transmitting light while also providing mechanical and environmental protection of LED 174 and allowing heat generated in LED 174 to be dissipated.

In some embodiments, transparent cover 178 can be coated with one or more anti-reflection coatings to increase light transmission. In some embodiments, additional optical components can be included in or supported by transparent cover 178. Examples of such optical components include lenses, mirrors, reflectors, collimators, beam splitters, beam combiners, dichroic mirrors, filters, polarizers, polarizing beam splitters, prisms, total internal reflection prisms, optical fibers, light guides and beam homogenizers.

In some embodiments, transparent cover 178 is disposed in close proximity to an upper surface 175 of LED 174. For example, in some embodiments, a spacing 190 between upper surface 175 of LED 174 and a lower surface 173 of transparent cover 178 nearest to upper surface 175 of LED 174 can be relatively small. For example, spacing 190 can be from about one micron to about 500 microns (e.g., at most about 500 microns, at most about 400 microns, at most about 300 microns, at most about 250 microns, at most about 150 microns, at most about 100 microns, at most about 50 microns, at most about 25 microns). In some embodiments, transparent cover 178 is disposed in contact with at least a portion of upper surface 175 of LED 174.

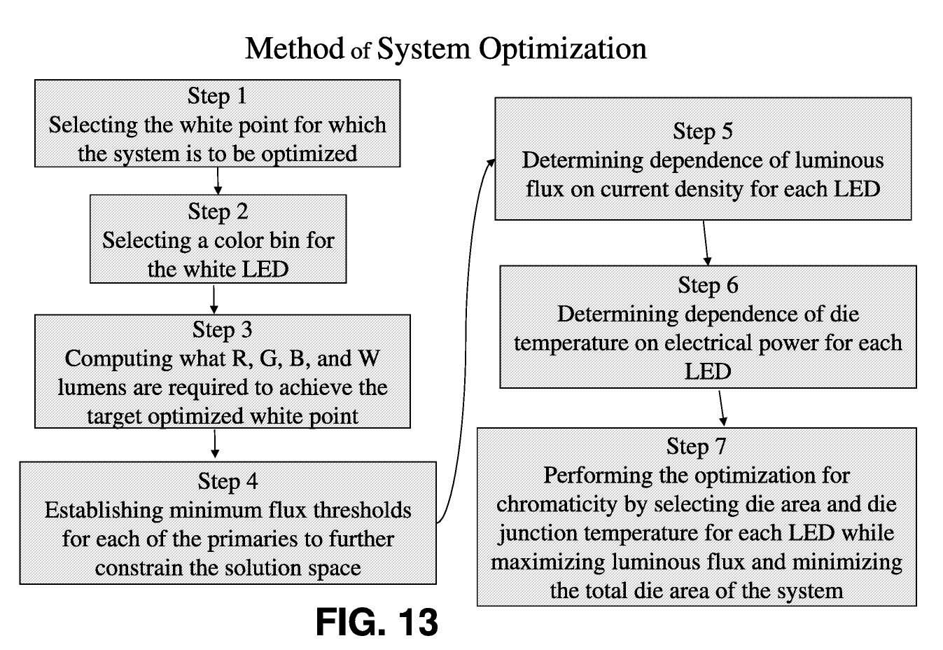

It may be beneficial to optimize the size of one or more (e.g., all) of the light emitting devices in the array individually in order to design an efficient LED system, especially for entertainment lighting application, where customers are interested in getting as much light as possible from the luminaries. In particular, performance in “white” mode is critical, because while LED luminaries excel at producing saturated colors (no light lost to filtering as in an incandescent subtractive color system), they can look weak compared to a white, unfiltered lamp. Two parameters should be optimized for entertainment light. First, total size of the emitting aperture must be minimized for best color mixing. Second, the thermal load on the red die must be minimized as red die junction temperature invariably limits system output operating in white color modes. Maximum allowable junction temperature is to be set by reliability expectations. The method of optimizing an LED system for minimum total die area and device junction temperature while maximizing luminous flux is disclosed by the present invention, as illustrated in FIG. 13. The method comprises the following steps: selecting the white point for which the system is to be optimized, selecting a color bin for the White LED, computing what Red, Green, Blue and White lumens are required to achieve the target optimized white point, establishing minimum flux thresholds for each of the primaries to further constrain the solution space, determining dependence of luminous flux on current density for each LED, determining dependence of die temperature on electrical power for each LED, and performing the optimization for chromaticity by optimizing die area and die junction temperature for each LED while maximizing luminous flux and minimizing the total die area of the system. Thus, expressing luminous flux in terms of LED current density, and die temperature in terms of LED current and nominal forward voltage (accounting for thermal crosstalk form one die to another), it is possible to parameterize the chromaticity optimization in terms of area of each LED and optimize for minimum die area and red die junction temperature while maximizing luminous flux.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

What is claimed is:

1. A system comprising:
a substrate; and
an array of light emitting devices supported by the substrate, the array of light emitting devices being configured such that at least one of the light emitting devices has an emitting area different than an emitting area of the other light emitting devices in the array.

2. The system of claim 1, wherein all of the light emitting devices in the array have different emitting areas.

3-4. (canceled)

5. The system of claim 1, wherein the array of light emitting devices comprises three light emitting devices.

6. The system of claim 5, wherein the array of light emitting devices is configured such that two light emitting devices in the array have equal emitting areas and another light emitting device in the array has an emitting area different than that of the two light emitting devices.

7. The system of claim 5, wherein the array comprises three light emitting devices having emitting areas different from each other.

8-9. (canceled)

10. The system of claim 1, wherein the array of light emitting devices comprises four light emitting devices.

11. The system of claim 10, wherein the array of light emitting devices is configured such that three light emitting devices have equal emitting areas, and another light emitting device in the array has emitting area different from that of said three light emitting devices.

12-16. (canceled)

17. The system of claim 1, wherein the array of light emitting devices comprises five light emitting devices.

18. The system of claim 17, wherein the array of light emitting devices is configured such that four light emitting devices have equal emitting areas and another light emitting device in the array has an emitting area different than that of said four light emitting devices.

19. The system of claim 17, wherein the array of light emitting devices is configured such that three light emitting devices have equal emitting areas and another two light emitting devices have equal emitting areas; the emitting area of the three light emitting devices being different than the emitting area of the other two light emitting devices.

20-25. (canceled)

26. The system of claim 1, wherein the array of light emitting devices comprises six light emitting devices.

27-39. (canceled)

40. The system of claim 1, wherein the array of light emitting devices being positioned such that a ratio of a sum of a total area of all of the light emitting devices in the array of light emitting devices to the area defined by the outer perimeter is at least about 0.75.

41. The system of claim 1, wherein the array of light emitting devices being positioned such that the spacing between the nearest edges of neighboring light emitting devices in the array is no more than 200 microns.

42-46. (canceled)

47. The system of claim 1, wherein the substrate is a portion of a package.

48-51. (canceled)

52. The system of claim 1, wherein at least one of the light emitting devices in the array of light emitting devices comprises a light emitting diode.

53-57. (canceled)

58. The system of claim 1, wherein the array comprises a Red LED and a Green LED and the array is configured such that the ratio of the emitting area of the Red LED to the emitting area of the Green LED is in the range from 0.7 to 1.3.

59. The system of claim 1, wherein the array comprises a Blue LED and a Red LED and the array is configured such that the ratio of the emitting area of the Blue LED to the emitting area of the Red LED is in the range from 0.15 to 0.75.

60. The system of claim 1, wherein the array comprises a Blue LED and a Green LED and the array is configured such that the ratio of the emitting area of the Blue LED to the emitting area of the Green LED is in the range from 0.15 to 0.75.

61. The system of claim 1, wherein the array comprises a Blue LED and a White LED and the array is configured such that the ratio of the emitting area of the Blue LED to the emitting area of the White LED is in the range from 0.3 to 0.9.

62. The system of claim 1, wherein the array comprises a White LED and a Red LED and the array is configured such that the ratio of the emitting area of the White LED to the emitting area of the Red LED is in the range from 0.45 to 1.05.

63. The system of claim 1, wherein the array comprises a White LED and a Green LED and the array is configured such that the ratio of the emitting area of the White LED to the emitting area of the Green LED is in the range from 0.45 to 1.05.

64-65. (canceled)

66. A method for optimization of an LED system comprising the steps of:
selecting the white point for which the system is to be optimized;
selecting a color bin for the White LED;
computing what Red, Green, Blue and White lumens are required to achieve the target optimized white point;
establishing minimum flux thresholds for each of the primaries to further constrain the solution space;
determining dependence of luminous flux on current density for each LED;
determining dependence of die temperature on electrical power for each LED; and
performing the optimization for chromaticity by selecting die area and die junction temperature for each LED while maximizing luminous flux and minimizing the total die area of the system.
